(19) United States
(12) Patent Application Publication
(10) Pub. No.: US 2024/0096655 A1
(43) Pub. Date: Mar. 21, 2024

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Katsuhiko Yamamoto, Toyama-shi (JP)

(73) Assignee: Kokusai Electric Corporation, Tokyo (JP)

(21) Appl. No.: 18/469,687

(22) Filed: Sep. 19, 2023

(30) Foreign Application Priority Data
Sep. 21, 2022 (JP) 2022-150565

(51) Int. Cl. H01L 21/67; H01J 37/32

(52) U.S. Cl. CPC H01L 21/67069; H01J 37/32201; H01J 37/32449; H01L 21/6719; H01L 21/67248; H01L 21/67276

(57) ABSTRACT

There is provided a technique that includes: a process chamber in which a substrate is processed; an electromagnetic wave generator configured to supply an electromagnetic wave into the process chamber; and a gas supplier through which a cooling gas is supplied to the substrate by adjusting a direction of supplying the cooling gas.

### CROSS-REFERENCE TO RELATED PATENT APPLICATION

This non-provisional U.S. patent application is based on and claims priority under 35 U.S.C. § 119 of Japanese Patent Application No. 2022-150565, filed on Sep. 21, 2022, in the Japanese Patent Office, the entire contents of which are hereby incorporated by reference.

### BACKGROUND

### 1. Field

The present disclosure relates to a substrate processing apparatus, a method of manufacturing a semiconductor device and a non-transitory computer-readable recording medium.

### 2. Related Art

According to some related arts, as a part of a manufacturing process of a semiconductor device, an annealing process may be performed. For example, the annealing process is performed by heating a substrate in a process chamber by using a heating structure such as a heater to change a composition or a crystal structure of a film formed on a surface of the substrate.

However, in the annealing process, a target film (that is, a film to be processed) may not be uniformly processed when the substrate cannot be uniformly heated.

### SUMMARY

According to the present disclosure, there is provided a technique capable of uniformly processing a substrate.

According to some embodiment of the present disclosure, there is provided a technique that includes: a process chamber in which a substrate is processed; an electromagnetic wave generator configured to supply an electromagnetic wave into the process chamber; and a gas supplier through which a cooling gas is supplied to the substrate by adjusting a direction of supplying the cooling gas.

### BRIEF DESCRIPTION OF THE DRAWINGS

FIG. 1 is a diagram schematically illustrating a vertical cross-section of a single wafer type process furnace of a substrate processing apparatus preferably used in a first embodiment of the present disclosure.

FIG. 2 is a block diagram schematically illustrating a configuration of a controller and related components of the substrate processing apparatus according to the first embodiment of the present disclosure.

FIG. 3 is a flow chart schematically illustrating a process flow of a substrate processing according to the first embodiment of the present disclosure.

FIG. 4 is a diagram schematically illustrating a relationship between a carrier density and a temperature of a substrate according to the first embodiment of the present disclosure.

FIG. 5 is a diagram schematically illustrating a configuration of a gas supplier of the substrate processing apparatus according to the first embodiment of the present disclosure.

FIG. 6A is a diagram schematically illustrating a gas flow in a case where the flow rate of the gas from a nozzle 105a is greater than the flow rate of the gas from a nozzle 105b in the gas supplier shown in FIG. 5, FIG. 6B is a diagram schematically illustrating the gas flow in a case where the flow rate of the gas from the nozzle 105a is equal to the flow rate of the gas from the nozzle 105b in the gas supplier shown in FIG. 5, and FIG. 6C is a diagram schematically illustrating the gas flow in a case where the flow rate of the gas from the nozzle 105a is smaller than the flow rate of the gas from the nozzle 105b in the gas supplier shown in FIG. 5.

FIG. 7A is a diagram schematically illustrating a vertical cross-section of a single wafer type process furnace of a substrate processing apparatus preferably used in a first modified example of the first embodiment of the present disclosure, and FIG. 7B is a diagram schematically illustrating a vertical cross-section of a single wafer type process furnace of a substrate processing apparatus preferably used in a second modified example of the first embodiment of the present disclosure.

FIG. 8 is a diagram schematically illustrating a vertical cross-section of a single wafer type process furnace of a substrate processing apparatus preferably used in a second embodiment of the present disclosure.

### DETAILED DESCRIPTION

### First Embodiment of Present Disclosure

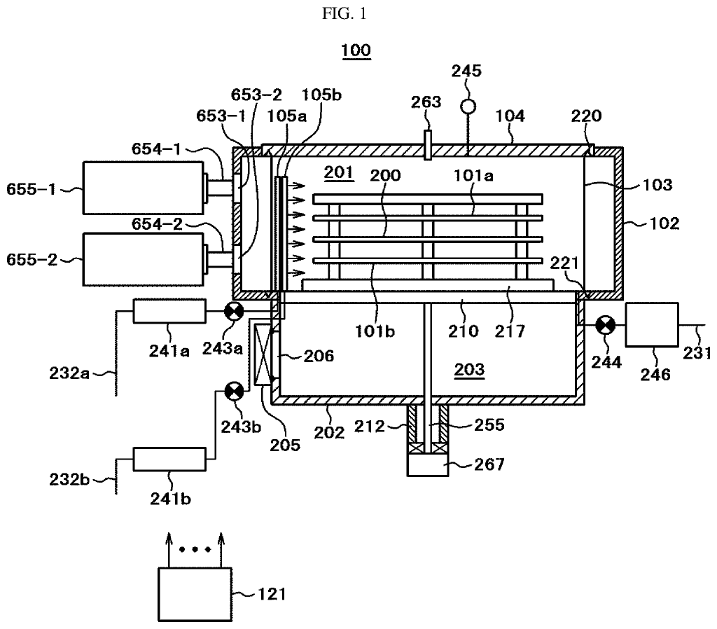

Hereinafter, a first embodiment of the technique of the present disclosure will be described in detail mainly with reference to FIGS. 1 through 5, FIGS. 6A through 6C and FIGS. 7A and 7B. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

According to the present embodiment, for example, a substrate processing apparatus 100 of the present disclosure is configured as a single wafer type heat treatment apparatus capable of performing various heat treatment processes on a wafer 200 serving as a substrate.

<Process Chamber>

As shown in FIG. 1, the substrate processing apparatus 100 according to the present embodiment may include: a case 102 serving as a cavity made of a material such as a metal capable of reflecting an electromagnetic wave; and a reaction tube 103 of a cylindrical shape accommodated in the case 102 and whose upper and lower ends in a vertical direction are open. For example, the reaction tube 103 is made of a material such as quartz capable of transmitting the electromagnetic wave. Further, a cap flange (which is a closing plate) 104 made of a metal material is in contact with the upper end of the reaction tube 103 to close (or seal) the upper end of the reaction tube 103 via an O-ring 220 serving as a sealing structure (which is a seal). A process vessel in which the substrate (that is, the wafer 200) such as a silicon wafer is processed is constituted mainly by the case 102, the reaction tube 103 and the cap flange 104, and in particular, a process chamber 201 is constituted by an inner space of the reaction tube 103.

A placement table (which is a mounting table) 210 is provided below the reaction tube 103, and a boat 217 serving as a substrate retainer (which is a substrate support) configured to hold (or support) the wafer 200 to be processed (or a plurality of wafers including the wafer 200) is placed on an upper surface of the placement table 210. Hereinafter, the plurality of wafers including the wafer 200 may also be simply referred to as “wafers 200”. The wafer 200 to be processed and heat insulating plates 101a and 101b are accommodated in the boat 217 such that the wafer 200 is interposed between the heat insulating plates 101a and 101b with a predetermined interval. For example, each of the heat insulating plates 101a and 101b may be configured as a quartz plate such as a dummy wafer or a silicon plate (Si plate). The heat insulating plates 101a and 101b are provided to maintain (retain) a temperature of the wafer 200. For example, on a side wall of the placement table 210, a protrusion (not shown) protruding in a radial direction of the placement table 210 is provided on a bottom of the placement table 210. When the protrusion approaches or comes into contact with a partition plate (not shown) provided between the process chamber 201 and a transfer space 203 described later, it is possible to prevent (or suppress) an inner atmosphere of the process chamber 201 from entering the transfer space 203 and an inner atmosphere of the transfer space 203 from entering the process chamber 201.

According to the present embodiment, a plurality of heat insulating plates serving as the heat insulating plate 101a and a plurality of heat insulating plates serving as the heat insulating plate 101b may be installed depending on a substrate processing temperature. By providing the plurality of heat insulating plates as the heat insulating plate 101a and the plurality of heat insulating plates as the heat insulating plate 101b, it is possible to suppress a heat dissipation in a region where the wafer 200 is placed, and it is also possible to improve a temperature uniformity on a surface of the wafer 200 or a temperature uniformity between the wafers 200. Further, a measurement window of a temperature sensor 263 is provided at an end plate (that is, a ceiling plate) of the boat 217. For example, a surface temperature of the heat insulating plate 101a is measured by the temperature sensor 263, and a process temperature of the wafer 200 is controlled based on a temperature measured by the temperature sensor 263. The process temperature in the present specification may refer to the temperature of the wafer 200 or an inner temperature of the process chamber 201.

For example, the case 102 serving as an upper vessel is a flat and sealed vessel with a circular horizontal cross-section. For example, a transfer vessel 202 serving as a lower vessel is made of a metal material such as aluminum (Al) and stainless steel (SUS), or is made of a material such as quartz. The transfer space 203 through which the wafer 200 serving as the substrate such as the silicon substrate is transferred is provided below the process vessel. A space above a bottom of the case 102 and surrounded by the case 102 (or surrounded by the reaction tube 103) may also be referred to as the “process chamber 201” or a “reaction region 201”. Further, a space below the bottom of the case 102 and surrounded by the transfer vessel 202 (that is, the transfer space 203 described above) may also be referred to as a “transfer region 203”.

A substrate loading/unloading port 206 is provided adjacent to a gate valve 205 at a side surface of the transfer vessel 202. The wafer 200 is transferred between the transfer space 203 and a substrate transfer chamber (not shown) through the substrate loading/unloading port 206.

Electromagnetic wave introduction ports 653-1 and 653-2 are provided (perforated) at a side surface of the case 102. A first end of a waveguide 654-1 and a first end of a waveguide 654-2 through which the electromagnetic wave is supplied into the process chamber 201 are connected to the electromagnetic wave introduction ports 653-1 and 653-2, respectively. A second end (the other end) of the waveguide 654-1 and a second end (the other end) of the waveguide 654-2 are connected to microwave oscillators (hereinafter, also referred to as “electromagnetic wave sources”) 655-1 and 655-2, respectively, serving as heating sources configured to supply the electromagnetic wave into the process chamber 201 to heat the process chamber 201.

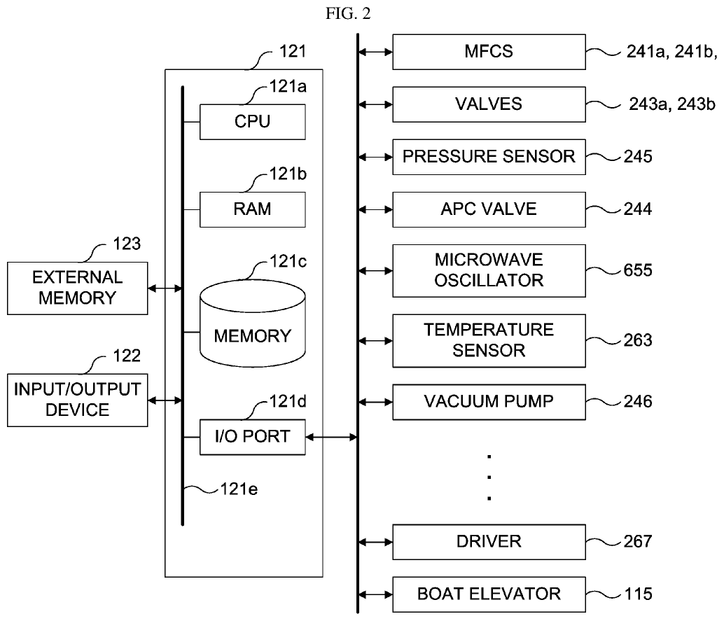

In the present specification, unless they need to be distinguished separately, as shown in FIG. 2, the electromagnetic wave introduction ports 653-1 and 653-2 may be collectively or individually referred to as an “electromagnetic wave introduction port 653”, the waveguides 654-1 and 654-2 may be collectively or individually referred to as a “waveguide 654”, and the microwave oscillators 655-1 and 655-2 may be collectively or individually referred to as a “microwave oscillator 655”.

The placement table 210 is supported by a shaft 255 serving as a rotating shaft. The shaft 255 penetrates a bottom of the transfer vessel 202, and is connected to a driver (which is a driving structure) 267 at an outside of the transfer vessel 202. The driver 267 is configured to rotate, elevate or lower the shaft 255. The wafer 200 accommodated in the boat 217 may be rotated, elevated or lowered by rotating, elevating or lowering the shaft 255 and the placement table 210 by operating the driver 267. For example, a bellows 212 covers a lower end of the shaft 255 and its periphery to maintain an inside of the process chamber 201 and an inside of the transfer region 203 airtight.

The placement table 210 is lowered until the upper surface of the placement table 210 reaches a position of the substrate loading/unloading port 206 (hereinafter, also referred to as a “wafer transfer position”) when the wafer 200 is transferred. Further, the placement table 210 is elevated until the wafer 200 reaches a process position in the process chamber 201 (hereinafter, also referred to as a “wafer processing position”) as shown in FIG. 1 when the wafer 200 is processed.

<Exhauster>

An exhauster (which is an exhaust structure) configured to exhaust the inner atmosphere of the process chamber 201 is provided below the process chamber 201 on an outer peripheral side of the placement table 210. As shown in FIG. 1, an exhaust port 221 is provided in the exhauster. An exhaust pipe 231 is connected to the exhaust port 221. A pressure regulator (which is a pressure adjusting structure) 244 such as an APC (Automatic Pressure regulator) valve and a vacuum pump 246 are sequentially connected to the exhaust pipe 231 in this order in series. For example, the APC valve capable of adjusting an opening degree thereof in accordance with an inner pressure of the process chamber 201 may be used as the pressure regulator 244. Thus, in the present specification, the pressure regulator 244 may also be referred to as an “APC valve 244”.

However, in the present embodiment, the pressure regulator 244 is not limited to the APC valve. The pressure regulator 244 may be embodied by a combination of a conventional opening/closing valve and a pressure regulating valve so long as it is possible to receive information on the inner pressure of the process chamber 201 (that is, a feedback signal from a pressure sensor 245 which will be described later) and to adjust an exhaust amount based on the information on the inner pressure of the process chamber 201 received from the pressure sensor 245.

The exhauster (also referred to as an “exhaust system” or an “exhaust line”) is constituted mainly by the exhaust port 221, the exhaust pipe 231 and the pressure regulator 244. It is also possible to provide an exhaust path to surround the process chamber 201 such that the gas can be exhausted from an entirety of a circumference of the wafer 200 through the exhaust path surrounding the process chamber 201. The exhauster may further include the vacuum pump 246.

<Gas Supplier>

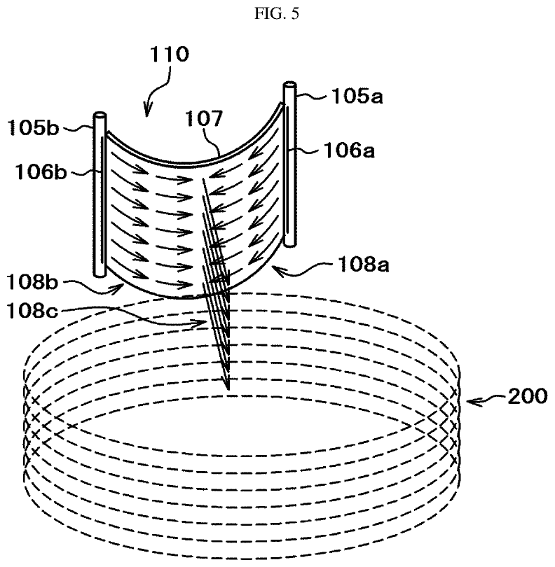

A nozzle 105a serving as a first nozzle and a nozzle 105b serving as a second nozzle are provided in an inner side of the reaction tube 103 through a lower surface of the case 102. A process gas such as an inert gas, a source gas and a reactive gas used for performing various substrate processing is supplied into the process chamber 201 though the nozzle 105a and the nozzle 105b. Gas supply pipes 232a and 232b are connected to the nozzles 105a and 105b, respectively. Mass flow controllers (MFCs) 241a and 241b serving as flow rate controllers (flow rate control structures) and valves 243a and 243b serving as opening/closing valves are sequentially installed at the gas supply pipes 232a and 232b, respectively in this order from upstream sides to downstream sides of the gas supply pipes 232a and 232b in a gas flow direction. For example, an inert gas supply source (not shown) is connected to the upstream sides of the gas supply pipes 232a and 232b, and the inert gas is supplied into the process chamber 201 via the MFCs 241a and 241b, the valves 243a and 243b and the nozzles 105a and 105b. For example, the inert gas is used as a cooling gas for cooling the wafer 200, as will be described later. When a plurality of types of gases are used for the substrate processing described later, a plurality of nozzles may be provided independently in accordance with the types of gases used for the substrate processing. A gas supplier (which is a gas supply system or a gas supply structure) 110 (see FIG. 5) is constituted mainly by the gas supply pipes 232a and 232b, the MFCs 241a and 241b and the valves 243a and 243b. The gas supplier 110 may further include the nozzles 105a and 105b and an arc-shaped plate 107 described later.

<Nozzle>

As shown in FIG. 5, the arc-shaped plate 107 serving as a curved structure is provided between the nozzle 105a and the nozzle 105b. For example, each of the nozzles 105a and 105b and the arc-shaped plate 107 may be made of quartz. Gas supply holes 106a and 106b through which a gas is supplied are provided on side surfaces of the nozzles 105a and 105b, respectively. The gas supply holes 106a and 106b are opened toward a direction of the arc-shaped plate 107 (that is, a direction tangential to an arc of the arc-shaped plate 107), and configured such that the gas is supplied parallel to the surface of the wafer 200. Each of the gas supply holes 106a and 106b is constituted by a slit or a plurality of rows of holes extending from a lower portion to an upper portion of the reaction tube 103. When the plurality of rows of holes are provided, an opening area of each of the plurality of rows of holes is the same, and each of the plurality of rows of holes is provided at the same opening pitch.

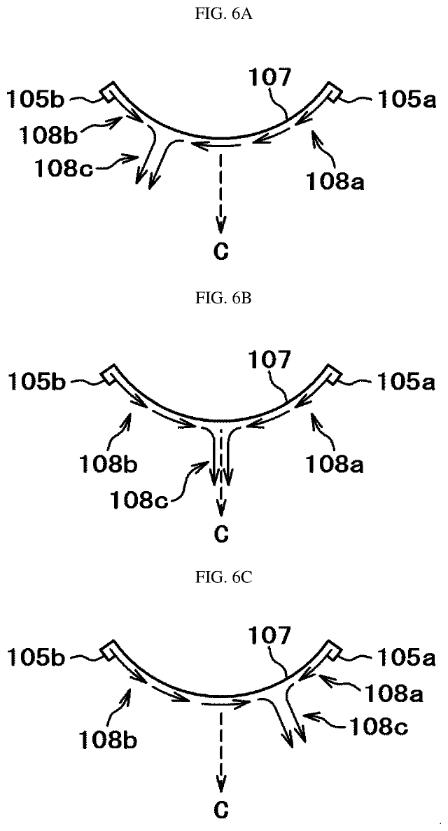

The gas supplier 110 is configured to be capable of adjusting a direction of supplying the gas by controlling a flow rate of the gas. Details of how to adjust the direction of supplying the gas will be described with reference to FIG. 5 and FIGS. 6A through 6C.

As shown in FIG. 5, a first gas 108a and a second gas 108b (which are respectively ejected through the gas supply holes 106a and 106b of the nozzles 105a and 105b serving as a part of the gas suppler 110 in the direction tangential to the arc of the arc-shaped plate 107) are supplied along a plate surface of the arc-shaped plate 107 by the Coanda effect. Since the arc-shaped plate 107 is curved so as to protrude toward the wafer 200, a third gas 108c obtained by synthesizing the first gas 108a and the second gas 108b is ejected onto the wafer 200 along a normal direction of the plate surface of the arc-shaped plate 107 (that is, a direction perpendicular to the plate surface of the arc-shaped plate 107). The third gas 108c is supplied between the heat insulating plate 101a and the wafer 200 and between the heat insulating plate 101b and the wafer 200. For example, when the boat 217 accommodates the wafers 200 in a multistage manner, the third gas 108c is supplied between the wafers 200. By adjusting flow rates of the first gas 108a and the second gas 108b with the MFCs 241a and 241b, respectively, it is possible to adjust an ejection direction of the third gas 108c.

For example, as shown in FIG. 6A, when the flow rate of the first gas 108a ejected through the nozzle 105a is greater than the flow rate of the second gas 108b ejected through the nozzle 105b, the third gas 108c is ejected toward a left portion (that is, a direction adjusted toward the nozzle 105b) with respect to a center of the wafer 200 (that is, a direction indicated by an arrow “C”).

For example, as shown in FIG. 6B, when the flow rate of the first gas 108a ejected through the nozzle 105a is equal to the flow rate of the second gas 108b ejected through the nozzle 105b, the third gas 108c is ejected toward the center of the wafer 200 (that is, the direction indicated by the arrow “C”).

For example, as shown in FIG. 6C, when the flow rate of the first gas 108a ejected through the nozzle 105a is smaller than the flow rate of the second gas 108b ejected through the nozzle 105b, the third gas 108c is ejected toward a right portion (that is, a direction adjusted toward the nozzle 105a) with respect to the center of the wafer 200 (that is, the direction indicated by the arrow “C”).

Since the third gas 108c obtained by synthesizing the first gas 108a and the second gas 108b, a flow rate of the third gas 108c is greater than the larger one of the flow rate of the first gas 108a and the flow rate of the second gas 108b. When the flow rate of the first gas 108a is indicated by “FA”, the flow rate of the second gas 108b is indicated by “FB” and the flow rate of the third gas 108c is indicated by “FC”, the FC can be indicated by “FC=FA+FB−α”. In the formula, a is a loss amount.

<Temperature Sensor>

The temperature sensor 263 serving as a non-contact type temperature detector (which is a measurer or a measuring structure) is provided at the cap flange 104. By adjusting an output of the microwave oscillator 655 described later (or an opening degree of each of the MFCs 241a and 241b) based on temperature information detected by the temperature sensor 263, the wafer 200 serving as the substrate is heated such that a desired temperature distribution of the wafer 200 can be obtained. For example, the temperature sensor 263 is constituted by a radiation thermometer such as an IR (Infrared Radiation) sensor.

Further, a method of measuring the temperature of the substrate (that is, the wafer 200) is not limited to using the radiation thermometer described above. For example, the temperature of the wafer 200 may be measured by using a thermocouple, or the temperature of the wafer 200 may be measured by using both of the thermocouple and the radiation thermometer. However, when the temperature of the wafer 200 is measured by using the thermocouple, in order to improve a temperature measurement accuracy of the thermocouple, it is preferable that the thermocouple is provided in the vicinity of the wafer 200 to be processed to measure the temperature the wafer 200. When the thermocouple is provided in the vicinity of the wafer 200, the thermocouple itself is heated by a microwave supplied from the microwave oscillator 655 described later. Therefore, it is preferable to use the radiation thermometer as the temperature sensor 263.

While the present embodiment is described by way of an example in which the temperature sensor 263 is provided at the cap flange 104, the present embodiment is not limited thereto. For example, the temperature sensor 263 may be provided at the placement table 210. With such a configuration, it is possible to use a reaction tube whose upper end is closed, and it is also possible to reduce a possibility of a leakage of, for example, the microwave and the process gas supplied to the process chamber 201.

For example, the temperature sensor 263 is directly disposed at the cap flange 104 or the placement table 210. However, instead of providing the temperature sensor 263 directly at the cap flange 104 or the placement table 210, the temperature sensor 263 may measure the temperature of the wafer 200 indirectly by measuring the radiation reflected by a component such as a mirror and emitted through a measurement window provided in the cap flange 104 or the placement table 210. When the temperature sensor 263 measures the temperature of the wafer 200 indirectly as described above, it is possible to relax a restriction on an installation location where the temperature sensor 263 is installed.

<Microwave Oscillator>

As described above, the electromagnetic wave introduction ports 653-1 and 653-2 are provided at a side wall (side surface) of the case 102. As described above, the first end of the waveguide 654-1 and the first end of the waveguide 654-2 through which the electromagnetic wave is supplied into the process chamber 201 are connected to the electromagnetic wave introduction ports 653-1 and 653-2, respectively. As described above, the second end (the other end) of the waveguide 654-1 and the second end (the other end) of the waveguide 654-2 are connected to the microwave oscillators (hereinafter, also referred to as the “electromagnetic wave sources” or “electromagnetic wave generators”) 655-1 and 655-2, respectively, serving as the heating sources configured to supply the electromagnetic wave into the process chamber 201 to heat the process chamber 201. The microwave oscillators 655-1 and 655-2 are configured to supply the electromagnetic wave such as the microwave to the waveguides 654-1 and 654-2, respectively. For example, a magnetron or a klystron may be used as each of the microwave oscillators 655-1 and 655-2. Preferably, a frequency of the electromagnetic wave generated by the microwave oscillator 655 is controlled such that the frequency is within a range from 13.56 MHz to 24.125 GHz. More preferably, the frequency is controlled to a frequency of 2.45 GHz or 5.8 GHz.

While the two microwave oscillators 655-1 and 655-2 are provided on the same side surface of the case 102 according to the present embodiment, the present embodiment is not limited thereto. For example, the microwave oscillator 655 including at least one microwave oscillator may be provided according to the present embodiment.

Alternatively, the microwave oscillator 655 may be provided on other side surface other than the above-mentioned side surface of the case 102. With such a configuration, it is possible to suppress an occurrence of regions described later in which the microwave is locally (or partially) absorbed on the wafer 200. That is, it is possible to suppress the wafer 200 from being locally heated, and as a result, it is also possible to improve the temperature uniformity on the surface of the wafer 200.

A microwave supplier (which is a microwave supply structure or a microwave supply apparatus) serving as a heater (heating structure) is constituted mainly by the microwave oscillators 655-1 and 655-2, the waveguides 654-1 and 654-2 and the electromagnetic wave introduction ports 653-1 and 653-2. The microwave supplier may also be referred to as an “electromagnetic wave supplier” which is an electromagnetic wave supply structure or an electromagnetic wave supply apparatus.

A controller 121 described later is connected to each of the microwave oscillators 655-1 and 655-2. The temperature sensor 263 configured to measure a temperature (surface temperature) of the heat insulating plate 101a (or the heat insulating plate 101b) or the temperature of the wafer 200 accommodated in the process chamber 201 is connected to the controller 121. The temperature sensor 263 may be configured to measure the temperature of the heat insulating plate 101a (or the heat insulating plate 101b) or the temperature of the wafer 200 and to transmit the measured temperature to the controller 121. The controller 121 is configured to control a heating of the wafer 200 by controlling the outputs of the microwave oscillators 655-1 and 655-2.

According to the present embodiment, for example, the microwave oscillators 655-1 and 655-2 are controlled by the same control signal transmitted from the controller 121. However, the present embodiment is not limited thereto. For example, the microwave oscillator 655-1 and the microwave oscillator 655-2 may be individually controlled by individual control signals transmitted from the controller 121 to the microwave oscillator 655-1 and the microwave oscillator 655-2, respectively.

<Controller>

As shown in FIG. 2, the controller 121 serving as a control structure or a control apparatus may be constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus 121e. For example, an input/output device 122 constituted by a component such as a touch panel is connected to the controller 121.

For example, the memory 121c is configured by a component such as a flash memory and an HDD (Hard Disk Drive). For example, a control program configured to control an operation of the substrate processing apparatus 100, an etching recipe containing information on sequences and conditions of an etching process for the nozzle described later or a process recipe containing information on sequences and conditions of a film-forming process may be readably stored in the memory 121c. The etching recipe or the process recipe is obtained by combining steps of the substrate processing described later such that the controller 121 can execute the steps to acquire a predetermined result, and functions as a program. Hereinafter, the etching recipe, the process recipe and the control program may be collectively or individually referred to as a “program”. Further, the etching recipe or the process recipe may be simply referred to as a “recipe”. Thus, in the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the MFCs 241a and 241b, the valves 243a and 243b, the pressure sensor 245, the APC valve 244, the vacuum pump 246, the temperature sensor 263, the driver 267 and the microwave oscillator 655.

The CPU 121a is configured to read the control program from the memory 121c and execute the read control program. Furthermore, the CPU 121a is configured to read the recipe from the memory 121c in accordance with an operation command inputted from the input/output device 122. In accordance with the contents of the read recipe, the CPU 121a may be configured to control various operations such as a flow rate adjusting operation for various gases by the MFCs 241a and 241b, an opening and closing operation of the valves 243a and 243b, an opening and closing operation of the APC valve 244, a pressure adjusting operation by the APC valve 244 based on the pressure sensor 245, a start and stop of the vacuum pump 246, an output adjusting operation by the microwave oscillator 655 based on the temperature sensor 263, an operation of adjusting a rotation and a rotation speed of the placement table 210 (or an operation of adjusting a rotation and a rotation speed of the boat 217) by the driver 267 and an elevating and lowering operation of the placement table 210 (or an elevating and lowering operation of the boat 217) by the driver 267.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

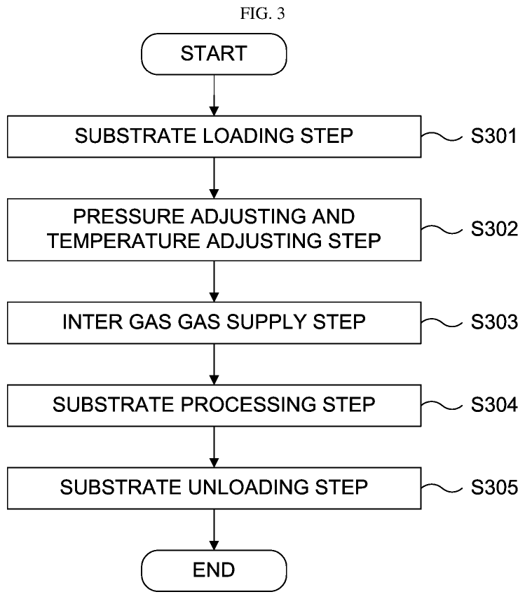

Hereinafter, an exemplary process flow of a method (that is, the substrate processing) of modifying (or crystallizing) a film formed on the wafer 200 serving as the substrate, which is a part of a manufacturing process of a semiconductor device, will be described with reference to a flow chart shown in FIG. 3. For example, the film such as an amorphous silicon film serving as a silicon-containing film is processed according to the substrate processing. The exemplary process flow of the substrate processing is performed by using the process furnace of the substrate processing apparatus 100 described above. Hereinafter, the components constituting the substrate processing apparatus 100 are controlled by the controller 121.

In the present specification, the term “wafer” may refer to “a wafer (product wafer) itself”, or may refer to “a wafer and a stacked structure (aggregated structure) of a predetermined layer (or layers) or a film (or films) formed on a surface of the wafer”. That is, when the term “wafer” collectively refers to the wafer and the layer (or layers) or the film (or films) formed on the surface of the wafer, the term “wafer” may refer to “a target substrate (target wafer)” alone, may refer to “a dummy substrate (dummy wafer)” alone, or may refer to both of “a target substrate (target wafer)” and “a dummy substrate (dummy wafer)”. Further, in the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”.

Thus, in the present specification, “supplying a predetermined gas to a wafer” may refer to “directly supplying a predetermined gas to a surface (exposed surface) of a wafer itself”, or may refer to “supplying a predetermined gas to a layer or a film formed on a wafer”, that is, “supplying a predetermined gas to a top surface (uppermost surface) of a wafer as a stacked structure”. In addition, in the present specification, “forming a predetermined layer (or film) on a wafer” may refer to “forming a predetermined layer (or film) directly on a surface (exposed surface) of a wafer itself” or may refer to “forming a predetermined layer (or film) on a layer (or film) formed on a wafer, i.e. a top surface (uppermost surface) of the wafer as a stacked structure”.

In the present specification, the terms “substrate” and “wafer” may be used as substantially the same meaning.

<Substrate Loading Step S301>

As shown in FIG. 1, after a predetermined number of wafers including the wafer 200 are transferred to the boat 217, the driver 267 elevates the placement table 210 such that the boat 217 is loaded (transferred) into the process chamber 201 in the reaction tube 103.

<Pressure Adjusting and Temperature Adjusting Step S302>

After the boat 217 is loaded into the process chamber 201, the inner atmosphere of the process chamber 201 is controlled (adjusted) such that the inner pressure of the process chamber 201 reaches and is maintained to a predetermined pressure (for example, a pressure within a range from 10 Pa to 102,000 Pa). Specifically, the opening degree of the pressure regulator 244 is feedback-controlled based on the pressure information detected by the pressure sensor 245 to adjust the inner pressure of the process chamber 201 to the predetermined pressure while vacuum-exhausting the process chamber 201 by the vacuum pump 246. In addition, simultaneously with controlling the inner atmosphere of the process chamber 201, the inner temperature of the process chamber 201 is controlled (adjusted) to a predetermined temperature by controlling the microwave supplier as a pre-heating operation. In the present specification, a notation of a numerical range such as “10 Pa to 102,000 Pa” means that a lower limit and an upper limit are included in the numerical range. Therefore, for example, the numerical range “from 10 Pa to 102,000 Pa” refers to a range equal to or higher than 10 Pa and equal to or lower than 102,000 Pa. The same also applies to other numerical ranges described in the present specification.

<Inert Gas Supply Step S303>

The driver 267 rotates the shaft 255 such that the wafer 200 is rotated via the boat 217 on the placement table 210. While the driver 267 rotates the wafer 200, the inert gas is supplied into the process chamber 201 through the gas supply pipes 232a and 232b and the nozzles 105a and 105b. In the present step, for example, the inner pressure of the process chamber 201 is adjusted to a predetermined pressure within a range from 0 Pa to 200,000 Pa, and preferably from 101,300 Pa to 101,600 Pa.

As the inert gas, nitrogen (N₂) gas or a rare gas such as argon (Ar) gas, helium (He) gas, neon (Ne) gas and xenon (Xe) gas may be used. The same also applies to the steps described below.

<Substrate Processing Step S304>

When the inner pressure of the process chamber 201 is maintained at the predetermined pressure, the microwave oscillators 655-1 and 655-2 heat the wafer 200 to a temperature within a range from 100° C. to 700° C., preferably from 200° C. to 600° C., and more preferably from 200° C. to 400° C. When the wafer 200 is to be processed at a temperature lower than 100° C. or at a temperature higher than 700° C., it is difficult for the wafer 200 to absorb the microwave. Thereby, it is not possible to efficiently heat the wafer 200.

The temperature of the wafer 200 can be estimated from the surface temperature of the heat insulating plate 101a measured by the temperature sensor 263 and temperature conversion data stored in advance in the memory 121c or in the external memory 123. The microwave oscillators 655-1 and 655-2 can supply the microwave into the process chamber 201 through the electromagnetic wave introduction ports 653-1 and 653-2 and the waveguides 654-1 and 654-2, respectively. Since the microwave supplied into the process chamber 201 enters the wafer 200 and is absorbed therein efficiently, it is possible to heat the wafer 200 very effectively.

After the wafer 200 is heated to the process temperature (which is predetermined) described above by controlling the microwave oscillator 655, the process temperature is maintained for a predetermined time. By controlling the microwave oscillator 655 in a manner described above, the amorphous silicon film formed on the surface of the wafer 200 is modified by the microwave. That is, a modification process is performed.

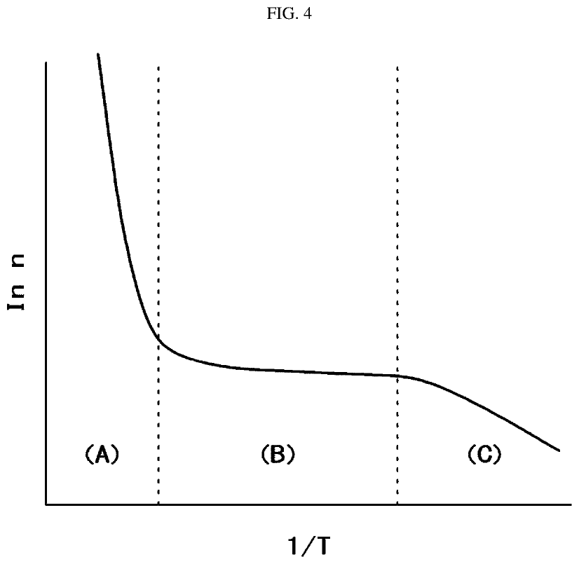

In the present embodiment, in order to heat the wafer 200 efficiently, that is, to efficiently absorb the microwave to wafer 200, it is preferable to consider a carrier density and a carrier temperature dependence of the wafer 200. FIG. 4 is a diagram schematically illustrating an example of a temperature dependence of the carrier density of the wafer 200. A vertical axis of the example shown in FIG. 4 represents the carrier density (which is proportional to the conductivity) n) and a horizontal axis of the example shown in FIG. 4 represents the temperature (1/T). In such a case, the temperature dependence of the carrier density can be divided into a region “(A)”, a region “(B)” and a region “(C)”. When the silicon substrate is used as the wafer 200, for example, a temperature separating the regions “(A)” and “(B)” is 327° C., and a temperature separating the regions “(B)” and “(C)” is −73° C. As is apparent from FIG. 4, in the regions “(A)” and “(C)”, the carrier density increases significantly as the temperature increases. However, in the region “(B)”, even when the temperature increases, the carrier density does not increase significantly.

Since a heat generation amount of the wafer 200 per unit time is proportional to the carrier density of the wafer 200, the heat generation amount changes as the carrier density fluctuates. Therefore, when a microwave heating process is performed in the region “(A)” where a change in the carrier density is large, a rate of increase in the carrier density according to a temperature change is large. As a result, even when an electric power of the microwave irradiated thereto is the same, a temperature elevation rate of the wafer 200 increases. Therefore, it is preferable that the microwave heating process is performed in the region “(A)”.

In addition, since the temperature elevation rate of the wafer 200 is high in the region “(A)” as described above, when the microwave is locally concentrated, a temperature of a portion where the microwave is locally concentrated becomes high, and a temperature difference is large locally within the surface of the wafer 200. As a result, the wafer 200 is deformed due to a difference in a thermal expansion. Therefore, by cooling the wafer 200 while heating the wafer 200 with the microwave in a temperature range of the region “(A)”, it is possible to improve a modification process speed of the wafer 200 while suppressing a deformation of the wafer 200 by reducing the temperature difference on the surface of the wafer 200.

The gas supplier may be controlled in accordance with the temperature measured by the temperature sensor 263 or the temperature estimated from the temperature conversion data described above and stored in advance. That is, at a timing when the temperature of the wafer 200 heated as described above is higher than a predetermined target temperature, by increasing an opening degree of the gas supplier, specifically, the opening degree of each of the MFCs 241a and 241b to increase a flow rate of the cooling gas, it is possible to cool the wafer 200. Conversely, at a timing when the temperature of the wafer 200 heated as described above is lower than the predetermined target temperature, by decreasing the opening degree of the gas supplier, specifically, the opening degree of each of the MFCs 241a and 241b to decrease the flow rate of the cooling gas, it is possible to heat the wafer 200. By controlling the microwave supplier and the gas supplier in a manner described above, for example, by precisely controlling the gas supplier alone to sufficiently perform a temperature control of the wafer 200, it is possible to simplify the temperature control of the wafer 200.

For example, it is preferable to control the MFCs 241a and 241b such that the flow rate of the cooling gas (that is, the flow rate of the third gas 108c) is within a range from 1 slm to 50 slm. When the flow rate of the cooling gas is less than 1 slm, the cooling gas may not reach the wafer 200. When the flow rate of the cooling gas is greater than 50 slm, the cooling gas may be wasted or the wafer 200 may be cooled too much.

For example, by controlling the flow rate by each of the MFCs 241a and 241b based on the temperature measured by the temperature sensor 263 or the temperature estimated from the temperature conversion data described above and stored in advance, it is possible to adjust a supply direction of the cooling gas such that the cooling gas is supplied toward a location of the wafer 200 where the temperature is the highest. Thereby, it is possible to adjust the temperature uniformity on the surface of the wafer 200.

By heating the wafer 200 as described above, the amorphous silicon film formed on the surface of the wafer 200 is modified (or crystallized) into a polysilicon film. That is, it is possible to uniformly modify the wafer 200.

After a predetermined process time has elapsed, the rotation of the boat 217, the supply of the gas, the supply of the microwave and the exhaust via the exhaust pipe 231 are stopped.

After the substrate processing step S304 is completed, the inert gas is supplied to return the inner pressure of the process chamber 201 to an atmospheric pressure.

<Substrate Unloading Step S305>

After returning the inner pressure of the process chamber 201 to the atmospheric pressure, the driver 267 lowers the placement table 210 to open a furnace opening, and transfers (unloads) the boat 217 to the transfer space 203 (boat unloading). After the boat 217 is unloaded, the wafer 200 accommodated in the boat 217 is transferred (discharged) from the transfer space 203 to the substrate transfer chamber (not shown) provided outside the transfer space 203.

By repeatedly performing the steps described above, the modification process is performed to the wafer 200.

### (3) Effects According to Present Embodiment

According to the present embodiment, it is possible to provide one or more of the following effects.

(a) Since the ejection direction of the cooling gas can be adjusted, it is possible to improve the temperature uniformity on the surface of the wafer 200.

(b) Since the ejection direction of the gas can be changed in accordance with the flow rate of the gas, the controller 121 can adjust the ejection direction. Thus, it is possible to ensure a reproducibility of a direction of the nozzle (that is, the ejection direction) as compared with a case where the direction of the nozzle is adjusted manually.

(c) Since the ejection direction of the gas can be adjusted by the flow rate of the gas, it is possible to change the ejection direction without using a mechanical structure (that is, a mechanical movable structure) capable of changing the direction of the nozzle. Thereby, it is possible to suppress an influence of an electromagnetic field distribution of the microwave generated when the mechanical structure is provided inside the reaction tube 103.

### (4) Modified Examples of First Embodiment

The substrate processing apparatus according to the present embodiment is not limited to a configuration described above, and may be modified as in modified examples described below. In a substrate processing apparatus according to the present modified examples, substantially the same components as those of the first embodiment will be denoted by like reference numerals, and detailed descriptions thereof will be omitted.

### First Modified Example

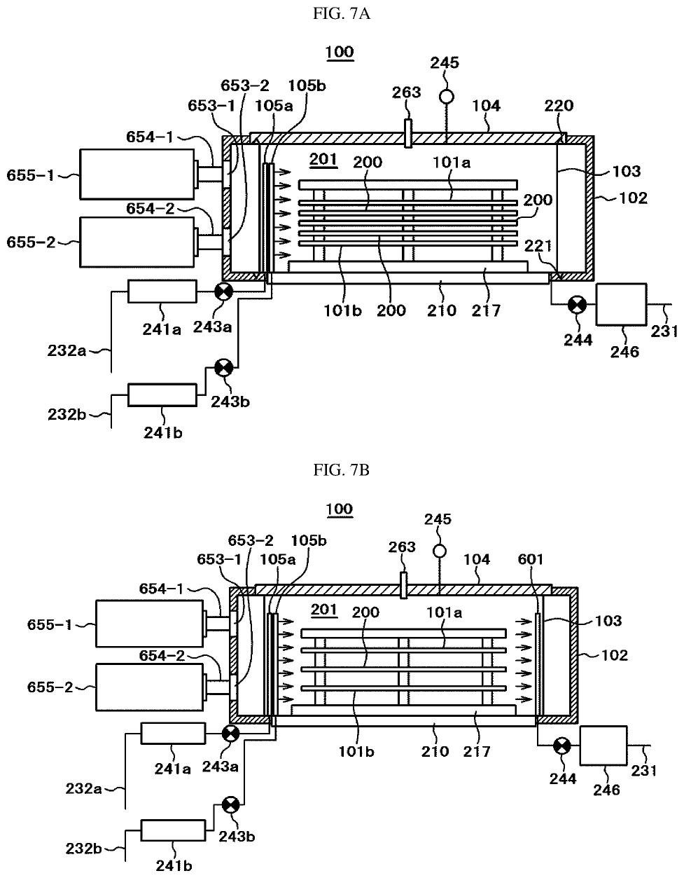

As shown in FIG. 7A, according to a first modified example of the first embodiment, the boat 217 is configured to be capable of accommodating the wafers 200 in a multistage manner. Specifically, the wafers 200 are provided between the heat insulating plates 101a and 101b accommodated in the boat 217. The wafers 200 are horizontally accommodated in the multistage manner at a predetermined interval therebetween. Thus, it is possible to uniformly process the wafers 200 by the substrate processing described above. With such a configuration, it is possible to process wafers 200 in one process, and it is also possible to improve a throughput of the substrate processing. Since each of the gas supply holes 106a and 106b is constituted by the slit or the plurality of rows of the holes extending from the lower portion to the upper portion of the reaction tube 103, it is possible to supply the gas between the wafers 200 through the nozzles 105a and 105b and the arc-shaped plate 107. Thereby, it is possible to improve the temperature uniformity between the wafers 200.

According to the first modified example, as shown in FIG. 7A, the wafers 200 are provided between the heat insulating plates 101a and 101b. However, the first modified example is not limited thereto. For example, a plurality of heat insulating plates including the heat insulating plate 101a and a plurality of heat insulating plates including the heat insulating plate 101b may be provided. Hereinafter, the plurality of heat insulating plates including the heat insulating plate 101a may also be simply referred to as “heat insulating plates 101a” and the plurality of heat insulating plates including the heat insulating plate 101b may also be simply referred to as “heat insulating plates 101b”. Then, each of the wafers 200 may be provided between a heat insulating plate among the heat insulating plate 101a and a heat insulating plate among the heat insulating plate 101b. With such a configuration, as compared with the first embodiment, it is possible to more quickly heat the wafer 200, and it is also possible to improve the temperature uniformity on the surface of the wafer 200.

### Second Modified Example

As shown in FIG. 7B, according to a second modified example of the first embodiment, an exhaust nozzle 601 through which the inner atmosphere of the process chamber 201 is exhausted is provided at a position facing the nozzles 105a and 105b with the boat 217 interposed therebetween. An exhaust port through which the inner atmosphere of the process chamber 201 is exhausted is provided on a side surface of the exhaust nozzle 601 facing the nozzles 105a and 105b, and the exhaust pipe 231 is connected at a downstream side of the exhaust nozzle 601. With such a configuration, even when the inner pressure of the process chamber 201 is the atmospheric pressure or in a slightly pressurized state, it is possible to horizontally supply the cooling gas through a side surface of the wafer 200 (that is, it is possible to to supply the cooling gas parallel to the surface of the wafer 200) so as to form a horizontal gas flow, and it is also possible to uniformly cool the wafer 200. Therefore, it is possible to improve the temperature uniformity on the surface of the wafer 200.

### Second Embodiment of Present Disclosure

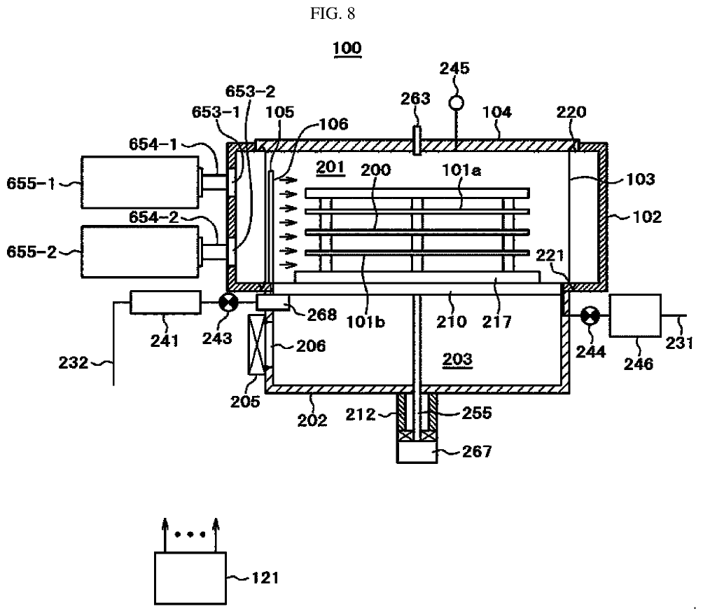

Hereinafter, a second embodiment of the technique of the present disclosure will be described in detail with reference to FIG. 8.

A substrate processing apparatus according to the second embodiment of the present disclosure is different from the substrate processing apparatus according to the first embodiment in that a rotator 268 capable of rotating a nozzle 105 (which serves as a part of a gas supplier of the second embodiment) is provided and the two nozzles 105a and 105b and the arc-shaped plate 107 of the first embodiment are not provided in the second embodiment. In the substrate processing apparatus according to the present embodiment, substantially the same components as those of the first embodiment will be denoted by like reference numerals, and detailed descriptions thereof will be omitted.

According to the present embodiment, the nozzle 105 is provided in the inner side of the reaction tube 103 through the lower surface of the case 102. The process gas such as the inert gas, the source gas and the reactive gas used for performing various substrate processing is supplied into the process chamber 201 though the nozzle 105. A gas supply hole 106 through which the gas is supplied is provided on a side surface of the nozzle 105. The gas is supplied parallel to the surface of the wafer 200 through the nozzle 105. The gas supply hole 106 is constituted by the slit or the plurality of rows of holes extending from the lower portion to the upper portion of the reaction tube 103. When the plurality of rows of holes are provided, the opening area of each of the plurality of rows of holes is the same, and each of the plurality of rows of holes is provided at the same opening pitch. The cooling gas ejected through the nozzle 105 is supplied between the heat insulating plate 101a and the wafer 200 and between the heat insulating plate 101b and the wafer 200. For example, when the boat 217 accommodates the wafers 200 in the multistage manner, the cooling gas is supplied between the wafers 200.

A gas supply pipe 232 is connected to the nozzle 105 via the rotator 268 described later. A mass flow controller (MFC) 241 serving as a flow rate controller (flow rate control structure) and a valve 243 serving as an opening/closing valve are sequentially installed at the gas supply pipe 232 in this order from an upstream side to a downstream side of the gas supply piped 232 in the gas flow direction. For example, the inert gas supply source (not shown) is connected to the upstream side of the gas supply pipe 232, and the inert gas is supplied into the process chamber 201 via the MFC 241, the valve 243. When a plurality of types of gases are used for the substrate processing, it is possible to supply the gases into the process chamber 201 by connecting one or more gas supply pipes to the gas supply pipe 232 at a downstream side of the valve 243 provided at the gas supply pipe 232. In such a case, an MFC and a valve are sequentially installed at each of the one or more gas supply pipes in order from an upstream side to a downstream side of each of the one or more gas supply pipes in the gas flow direction. A gas supplier (also referred as a “gas supply system” or a “gas supply structure”) according to the present embodiment is constituted mainly by the gas supply pipe 232, the MFC 241 and the valve 243. The gas supplier may further include at least one among the nozzle 105 and the rotator 268.

The rotator 268 capable of rotating the nozzle 105 is provided below the reaction tube 103 and on an outer peripheral side of the transfer vessel 202. By rotating the nozzle 105 by operating the rotator 268 by the controller 121, it is possible to adjust a direction of the cooling gas ejected through the gas supply hole 106. Further, the controller 121 is capable of controlling the rotator 268 to adjust the direction of the cooling gas based on measurement results of the temperature sensor 263. With such a configuration, it is possible to obtain substantially the same effects as in the first embodiment described above, and it is also possible to simplify a control of the gas supplier without complicating an apparatus structure in the reaction tube 103 as compared with the first embodiment. Since the rotator 268 (which is a mechanical structure) is not provided in the reaction tube 103, it is possible to suppress the influence of the electromagnetic field distribution of the microwave generated when the mechanical structure is provided.

### Other Embodiments of Present Disclosure

While the technique of the present disclosure is described in detail by way of the embodiments and the modified examples described above, the technique of the present disclosure is not limited thereto. The technique of the present disclosure may be modified in various ways without departing from the scope thereof. For example, the embodiments described above and the modified examples described above may be appropriately combined. Even in such a case, it is possible to obtain substantially the same effects as in the embodiments described above. The process sequences and the process conditions of each combination thereof may be substantially the same as those of the embodiments described above or the modified examples described above.

For example, the embodiments described above are described by way of an example in which the amorphous silicon film serving as the film containing silicon as a primary element (main element) is modified into the polysilicon film by performing the modification process. However, the technique of the present disclosure is not limited thereto. For example, the technique of the present disclosure may be applied to modify a film formed on the surface of the wafer 200 by supplying a gas containing at least one among oxygen (O), nitrogen (N), carbon (C) and hydrogen (H). For example, when a hafnium oxide film (HfₓO_{y} film) serving as a high dielectric film is formed on the wafer 200, a deficient oxygen in the hafnium oxide film can be supplemented and the characteristics of the high dielectric film can be improved by supplying the microwave to heat the wafer 200 while supplying a gas containing oxygen. For example, when the hafnium oxide film (HfₓO_{y} film) is formed on the wafer 200, an uncrystallized portion in the hafnium oxide film can be crystallized and the characteristics of the high dielectric film can be improved by supplying the microwave to heat the wafer 200 while supplying a gas containing nitrogen such as the N₂ gas.

While the hafnium oxide film is mentioned above as an example, the technique of the present disclosure is not limited thereto. For example, the technique of the present disclosure may be preferably applied to modify a metal-based oxide film, that is, an oxide film containing at least one metal element among aluminum (Al), titanium (Ti), zirconium (Zr), tantalum (Ta), niobium (Nb), lanthanum (La), cerium (Ce), yttrium (Y), barium (Ba), strontium (Sr), calcium (Ca), lead (Pb), molybdenum (Mo) and tungsten (W). That is, the substrate processing described above may be preferably applied to modify a film formed on the wafer 200 such as a Ti film, a TiN film, a TiOCN film, a TiOC film, a TiON film, a TiO film, a ZrN film, a ZrOCN film, a ZrOC film, a ZrON film, a ZrO film, a HfOCN film, a HfOC film, a HfON film, a HfO film, a TaOCN film, a TaOC film, a TaON film, a TaO film, a NbOCN film, a NbOC film, a NbON film, a NbO film, an AlOCN film, an AlOC film, an AlON film, an AlO film, a MoOCN film, a MoOC film, a MoON film, a MoO film, a W film, a WOCN film, a WOC film, a WON film and a WO film.

Further, without being limited to the high dielectric film, it is also possible to heat a film containing silicon as a primary element (main element) and doped with impurities. A silicon-based film such as a silicon nitride film (SiN film), a silicon oxide film (SiO film), a silicon oxycarbide film (SiOC film), a silicon oxycarbonitride film (SiOCN film) and a silicon oxynitride film (SiON film) may be used as the above-mentioned film containing silicon as the primary element. For example, an epi-Si film or an epi-SiGe film may also be used as the above-mentioned film containing silicon as the primary element. For example, the impurities may include at least one metal element such as boron (B), carbon (C), nitrogen (N), aluminum (Al), phosphorus (P), gallium (Ga) and arsenic (As). In addition to or instead of the film containing silicon as the primary element and the metal oxide film described above, an epi-Ge film or a film formed using the group 3 element and the group 5 element may be heated.

In addition, the technique of the present disclosure may be applied to process a photoresist film based on at least one photoresist among methyl methacrylate resin (polymethyl methacrylate, PMMA), epoxy resin, novolac resin or polyvinyl phenyl resin.

For example, the embodiments described above are described by way of an example in which the substrate processing is performed as a part of the manufacturing process of the semiconductor device. However, the technique of the present disclosure is not limited thereto. For example, the technique of the present disclosure may be applied to other substrate processing such as a patterning process of a manufacturing process of a liquid crystal panel, a patterning process of a manufacturing process of a solar cell and a patterning process of a manufacturing process of a power device.

For example, the embodiments described above are described by way of an example in which a single wafer type substrate processing apparatus capable of processing one or several substrates at a time is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses exemplified above may be substantially the same as those of the embodiments or the modified examples described above. Even in such a case, it is possible to obtain substantially the same effects according to the embodiments or the modified examples described above.

According to some embodiments of the present disclosure, it is possible to uniformly process the substrate.

What is claimed is:

1. A substrate processing apparatus comprising:
a process chamber in which a substrate is processed;
an electromagnetic wave generator configured to supply an electromagnetic wave into the process chamber; and
a gas supplier through which a cooling gas is supplied to the substrate by adjusting a direction of supplying the cooling gas.

2. The substrate processing apparatus of claim 1, wherein the gas supplier comprises:
a first nozzle through which the cooling gas is supplied;
a second nozzle through which the cooling gas is supplied; and
a curved structure provided between the first nozzle and the second nozzle.

3. The substrate processing apparatus of claim 2, wherein the curved structure comprises an arc-shaped plate curved so as to protrude toward the substrate.

4. The substrate processing apparatus of claim 2, wherein the first nozzle and the second nozzle are configured such that the cooling gas is supplied toward the curved structure.

5. The substrate processing apparatus of claim 2, wherein the gas supplier is configured such that the cooling gas is supplied between adjacent substrates among a plurality of substrates.

6. The substrate processing apparatus of claim 2, further comprising
a controller configured to be capable of adjusting a direction of the cooling gas supplied to the substrate by controlling a flow rate of the cooling gas supplied through each of the first nozzle and the second nozzle.

7. The substrate processing apparatus of claim 6, further comprising
a measurer capable of measuring a temperature of the substrate,
wherein the controller is further configured to be capable of adjusting the direction of the cooling gas based on measurement results of the measurer.

8. The substrate processing apparatus of claim 7, wherein the controller is further configured to be capable of controlling the measurer to measure the temperature of the substrate and controlling the gas supplier to supply the cooling gas toward a location of the substrate where the temperature thereof is highest.

9. The substrate processing apparatus of claim 5, wherein each of the first nozzle and the second nozzle is provided with a plurality of holes through which the cooling gas is capable of being supplied to the plurality of substrates.

10. The substrate processing apparatus of claim 5, wherein each of the first nozzle and the second nozzle is provided with a slit through which the cooling gas is capable of being supplied to the plurality of substrates.

11. The substrate processing apparatus of claim 1, further comprising a rotator,
wherein the gas supplier comprises a nozzle through which the cooling gas is supplied, and
wherein the rotator is capable of rotating the nozzle.

12. The substrate processing apparatus of claim 11, wherein the gas supplier is configured such that the cooling gas is supplied between adjacent substrates among a plurality of substrates.

13. The substrate processing apparatus of claim 12, further comprising
a controller configured to be capable of adjusting a direction of the cooling gas supplied to the substrate by controlling the rotator.

14. The substrate processing apparatus of claim 13, further comprising
a measurer capable of measuring a temperature of the substrate,
wherein the controller is further configured to be capable of adjusting the direction of the cooling gas based on measurement results of the measurer.

15. The substrate processing apparatus of claim 14, wherein the controller is further configured to be capable of controlling the rotator to supply the cooling gas toward a location of the substrate where the temperature thereof is highest based on the measurement results of the measurer.

16. The substrate processing apparatus of claim 12, wherein the nozzle is provided with a plurality of holes through which the cooling gas is capable of being supplied to the plurality of substrates.

17. The substrate processing apparatus of claim 12, wherein the nozzle is provided with a slit through which the cooling gas is capable of being supplied to the plurality of substrates.

18. The substrate processing apparatus of claim 13, further comprising
a measurer capable of measuring a temperature of the substrate,
wherein the controller is further configured to be capable of adjusting the direction of the cooling gas based on measurement results of the measurer.

19. A method of manufacturing a semiconductor device, comprising:
(a) supplying an electromagnetic wave into a process chamber of a substrate processing apparatus, wherein the substrate processing apparatus comprises:
the process chamber in which a substrate is processed;
an electromagnetic wave generator configured to supply the electromagnetic wave into the process chamber; and
a gas supplier through which a cooling gas is supplied to the substrate by adjusting a direction of supplying the cooling gas; and
(b) supplying the cooling gas to the substrate.

20. A non-transitory computer-readable recording medium storing a program that causes a substrate processing apparatus, by a computer, to perform:
(a) supplying an electromagnetic wave into a process chamber of a substrate processing apparatus, wherein the substrate processing apparatus comprises:
the process chamber in which a substrate is processed;
an electromagnetic wave generator configured to supply the electromagnetic wave into the process chamber; and
a gas supplier through which a cooling gas is supplied to the substrate by adjusting a direction of supplying the cooling gas; and
(b) supplying the cooling gas to the substrate.
